(19) United States
(12) Patent Application Publication
(10) Pub. No.: US 2026/0350876 A1
(43) Pub. Date: Nov. 5, 2026

(54) AUTOMATICALLY GENERATING TEXTUAL CONTENT FOR VISUAL ASSETS IN A DESIGN ENVIRONMENT

(71) Applicant: FIGMA, INC., San Francisco, CA (US)

(72) Inventors: Mengyuan WU, Seattle, WA (US); Hannah Luo YAN, San Francisco, CA (US); Yi Tang Jackie CHUI, Bellevue, WA (US); Linda QIN, Redmond, WA (US); Daniel Mejia VALENCIA, Seattle, CA (US)

(21) Appl. No.: 19/197,906

(22) Filed: May 2, 2025

(51) Int. Cl. G06T 11/60; G06F 30/12; G06F 40/40; G06T 7/11; G06T 9/00

(52) U.S. Cl. CPC G06T 11/60; G06F 30/12; G06F 40/40; G06T 7/11; G06T 9/00; G06T 2207/20021

(57) ABSTRACT

Embodiments of the present disclosure provide techniques for efficiently generating textual outputs for visual assets in a design environment using generative artificial intelligence models. An example method generally includes receiving a request to generate textual content for a visual asset in a graphic design rendered in a design environment. A text representation of the graphic design is generated based on an identity of the visual asset. Textual content for the visual asset is generated using a generative artificial intelligence model and the text representation of the graphic design. The visual asset is rendered in the design environment with the generated textual content.

### BACKGROUND

### Field of the Various Embodiments

Embodiments of the present disclosure relate generally to text generation using a generative artificial intelligence model in a computing system and, more specifically, to techniques for efficiently generating text for visual assets in a design environment using a generative artificial intelligence model.

### Description of the Related Art

Graphic design tools generally allow for the creation of visual assets in a design environment. These visual assets may be defined, for example, as vector assets defined in terms of mathematical relationships between different components or raster assets defined in terms of absolute pixel locations. In some cases, a visual asset may include one or more containers, defined in the vector space, in which raster assets (e.g., images) can be inserted. A visual asset may include any number of visual components, and a visual asset may be defined in terms of relative positioning or other spatial relationships between visual components in the visual asset.

Visual assets can include textual content that is displayed when visual assets are displayed in a design environment provided by a graphic design tool. The textual content may generally differ based on the context around a visual asset, such as the location of a visual asset in a graphic design, adjacent visual assets in the graphic design, and so on. For example, textual content in a header portion of the graphic design may relate to how to navigate through different portions of a workflow designed in a design environment. In contrast, textual content in a different portion of the graphic design may relate to content delivered to a user interacting with a portion of a workflow.

Generative artificial intelligence models can be used, in some cases, to generate the text for a visual asset displayed in a design environment. Generally, a language model, which may be a generative artificial intelligence model trained to generate a textual output to an input prompt specifying properties of the textual output, generates textual content that can be associated with the visual asset. While generative artificial intelligence models can generate textual content in response to a variety of input prompts, generative artificial intelligence models may not be able to generate textual outputs that are contextually accurate or otherwise usable. For example, generative artificial intelligence models may not be able to generate relevant textual content for a specific visual asset rendered in the design environment without contextual information about the visual asset and other visual assets in the design environment. Further, due to the size of graphic designs rendered in a design environment, providing contextual information about a graphic design to a generative artificial intelligence model may be inefficient and may increase the amount of computational resources used by a generative artificial intelligence model in generating a textual output for a visual asset.

As the foregoing illustrates, what is needed are more effective techniques for automatically generating textual outputs for visual assets in a design environment.

### SUMMARY

One embodiment of the present disclosure provides techniques for efficiently generating textual outputs for visual assets in a design environment using generative artificial intelligence models. An example method generally includes receiving a request to generate textual content for a visual asset in a graphic design rendered in a design environment. A text representation of the graphic design is generated based on an identity of the visual asset. Textual content for the visual asset is generated using a generative artificial intelligence model and the text representation of the graphic design. The visual asset is rendered in the design environment with the generated textual content.

One technical advantage of the disclosed techniques relative to the prior art is that the disclosed techniques allow for efficient generation of contextually relevant textual content for visual assets in a design environment. As discussed in further detail herein, embodiments disclosed herein generate textual content for a visual asset in a graphic design based on a textual representation of the graphic design. By providing the textual representation of the graphic design to a generative artificial intelligence model as contextual information, the generative artificial intelligence model can generate textual content for the visual asset based on relationships between the visual asset and other visual assets in the graphic design. These relationships may include, for example, spatial relationships, parent-child relationships, and other relationships that can be used as contextual clues for the appropriate textual content to be generated for a visual asset. Further, embodiments presented herein may adjust the content of the textual representation of the graphic design based on the identity of the visual asset for which a generative artificial intelligence model is to generate text. By doing so, embodiments of the present disclosure may reduce the amount of data ingested by a generative artificial intelligence model and processed in order to generate a textual output. Thus, embodiments of the present disclosure may reduce the computational expense involved in generating a textual output using a generative artificial intelligence model while allowing the generative artificial intelligence model to generate contextually relevant text outputs.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a computer system configured to implement one or more aspects of various embodiments of the present disclosure.

FIG. 2 is a message flow diagram illustrating messages exchanged between a graphic design engine and a text suggestion engine to generate textual content for visual assets rendered in a design environment, according to some embodiments.

FIG. 3 illustrates example operations for generating textual content for a visual asset rendered in a design environment based on a textual representation of a graphic design associated with the visual asset, according to some embodiments.

FIG. 4 illustrates a network computing system to implement an interactive graphic application platform, according to some embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

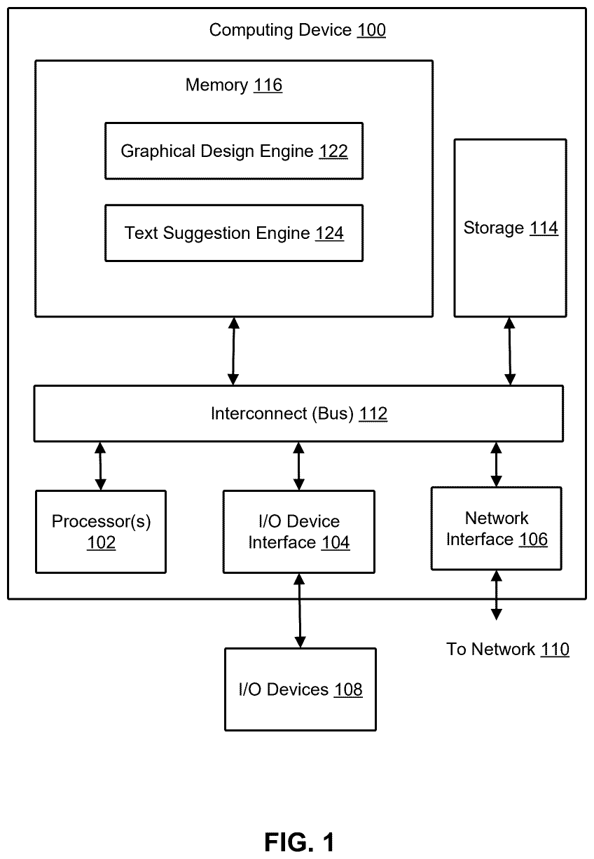

FIG. 1 illustrates a computing device 100 configured to implement one or more aspects of various embodiments of the present invention. In one embodiment, computing device 100 includes a desktop computer, a laptop computer, a smart phone, a personal digital assistant (PDA), tablet computer, or any other type of computing device configured to receive input, process data, and optionally display images, and is suitable for practicing one or more embodiments. Computing device 100 is configured to run graphical design engine 122 and/or text suggestion engine 124 that reside in a memory 116.

It is noted that the computing device described herein is illustrative and that any other technically feasible configurations fall within the scope of the present disclosure. For example, multiple instances of graphical design engine 122 and/or text suggestion engine 124 could execute on a set of nodes in a distributed and/or cloud computing system to implement the functionality of computing device 100. In another example, graphical design engine 122 and/or text suggestion engine 124 could execute on various sets of hardware, types of devices, or environments to adapt graphical design engine 122 and/or text suggestion engine 124 to different use cases or applications. In a third example, graphical design engine 122 and/or text suggestion engine 124 could execute on different computing devices and/or different sets of computing devices.

In one embodiment, computing device 100 includes, without limitation, an interconnect (bus) 112 that connects one or more processors 102, an input/output (I/O) device interface 104 coupled to one or more input/output (I/O) devices 108, memory 116, a storage 114, and a network interface 106. Processor(s) 102 may be any suitable processor implemented as a central processing unit (CPU), a graphics processing unit (GPU), an application-specific integrated circuit (ASIC), a field programmable gate array (FPGA), an artificial intelligence (AI) accelerator, any other type of processing unit, or a combination of different processing units, such as a CPU configured to operate in conjunction with a GPU. In general, processor(s) 102 may be any technically feasible hardware unit capable of processing data and/or executing software applications. Further, in the context of this disclosure, the computing elements shown in computing device 100 may correspond to a physical computing system (e.g., a system in a data center) or may be a virtual computing instance executing within a computing cloud.

I/O devices 108 include devices capable of providing input, such as a keyboard, a mouse, a touch-sensitive screen, a microphone, and so forth, as well as devices capable of providing output, such as a display device or speaker. Additionally, I/O devices 108 may include devices capable of both receiving input and providing output, such as a touchscreen, a universal serial bus (USB) port, and so forth. I/O devices 108 may be configured to receive various types of input from an end-user (e.g., a designer) of computing device 100, and to also provide various types of output to the end-user of computing device 100, such as displayed digital images or digital videos or text. In some embodiments, one or more of I/O devices 108 are configured to couple computing device 100 to a network 110.

Network 110 is any technically feasible type of communications network that allows data to be exchanged between computing device 100 and external entities or devices, such as a web server or another networked computing device. For example, network 110 may include a wide area network (WAN), a local area network (LAN), a wireless (Wi-Fi) network, and/or the Internet, among others.

Storage 114 includes non-volatile storage for applications and data, and may include fixed or removable disk drives, flash memory devices, and CD-ROM, DVD-ROM, Blu-Ray, HD-DVD, or other magnetic, optical, or solid-state storage devices. Graphical design engine 122 and/or text suggestion engine 124 may be stored in storage 114 and loaded into memory 116 when executed.

Memory 116 includes a random-access memory (RAM) module, a flash memory unit, or any other type of memory unit or combination thereof. Processor(s) 102, I/O device interface 104, and network interface 106 are configured to read data from and write data to memory 116. Memory 116 includes various software programs that can be executed by processor(s) 102 and application data associated with said software programs, including graphical design engine 122 and/or text suggestion engine 124.

### Example Efficient Text Generation for Visual Assets Rendered in a Design Environment Using Generative Artificial Intelligence Models

Generally, a design environment such as that hosted by graphical design engine 122 allows for the creation of graphical user interfaces and, in some cases, functionality attached to different portions of the graphical user interfaces. These graphical user interfaces may be created for different portions of a workflow executed in an application, by navigating a web site including a plurality of web pages, or the like. Generally, the design environment allows for different design files to be created and visualized in a staging or design environment that is isolated from an execution environment in which the completed graphical user interfaces and associated functionality is eventually to be deployed.

Textual content associated with a visual asset can be added, removed, and modified in the design environment provided by graphical design engine 122. Generally, the textual content associated with a visual asset may be defined based on the context of the visual asset. For example, as discussed, visual assets associated with a navigation pane may include textual content describing workflows to which a user can navigate. In contrast, visual assets associated with content panes in the graphic design may include textual content associated with different types of content rendered in these panes. For example, a content pane associated with the primary content being delivered in a graphic design (e.g., video content contained within the content pane, image content contained within the content pane, etc.) may include textual content describing the primary content. Meanwhile, a content pane associated with user interaction associated with the primary content may include textual content such as user comments, reviews, or the like.

When a graphical design is being created within the design environment provided by graphical design engine 122, text associated with visual assets may be created, removed, and/or modified to allow for the overall look and feel of the graphical design to be previewed. As discussed, generative artificial intelligence models, such as language models, can be used to generate the textual content to be displayed within a visual asset rendered in the design environment. However, without contextual information, a generative artificial intelligence model may not be able to generate textual content that is contextually relevant for any given visual asset in the graphic design. Further, contextual information associated with a visual asset for which textual content is to be generated may be a large amount of data that may result in the use of a large amount of computational resources (e.g., memory, processing cycles, power) when ingested and used by a generative artificial intelligence model to generate textual content.

To provide for efficient generation of contextually relevant textual content for visual assets in a design environment, embodiments of the present disclosure provide techniques for generating textual content using a generative artificial intelligence model based on contextual information associated with a visual asset. When a triggering event occurs with respect to the textual content included in or otherwise associated with a visual asset, a text representation of the graphic design associated with the visual asset may be generated. This text representation may convert a graphic design, or a relevant portion thereof, into a textual format including information about the location of other visual assets in the graphic design, the content of these visual assets, alignment information, and the like. By doing so, embodiments of the present disclosure may allow a generative artificial intelligence model to generate contextually relevant textual content for visual assets in a design environment. A generative artificial intelligence model may generate this contextually relevant textual content using fewer computing resources than would be used when other, potentially irrelevant or less relevant, contextual information is also provided to the generative artificial intelligence model as an input.

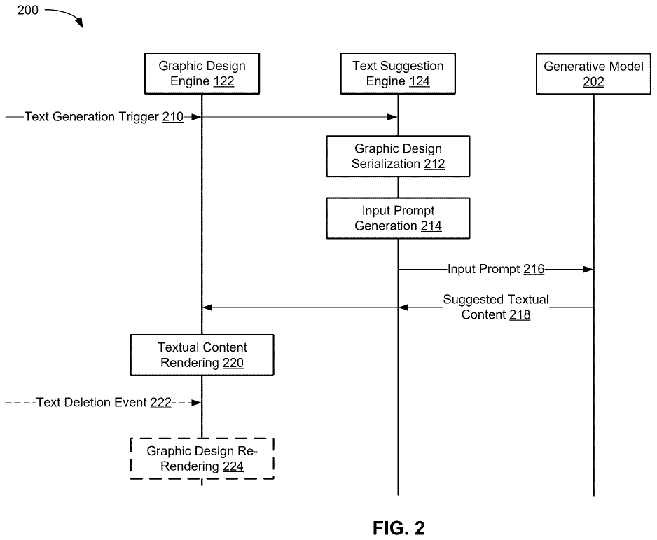

FIG. 2 is a message flow diagram 200 illustrating messages exchanged between a graphic design engine and a text suggestion engine to generate textual content for visual assets rendered in a design environment, according to some embodiments.

Within a design environment provided by graphic design engine 122 in which graphic designs and the visual assets contained therein are rendered, a plurality of graphic designs may be rendered on a canvas. Each graphic design may be associated with a design file that is associated with a particular portion of a workflow to be executed on a client device. For example, one graphic design may correspond to a landing page or home page to which a user is directed in order to begin interaction with an application, while another graphic design may correspond to a page in which specific content is presented to a user of the application. Generally, the textual content associated with a visual asset may be influenced by the graphic design in which the visual asset is contained but may not be influenced, or may only be weakly influenced, by other graphic designs rendered in the design environment.

Generally, visual assets rendered in the design environment provided by graphic design engine 122 may be represented in a tree data structure or other data structure in which parent-child relationships are preserved. In some embodiments, because the design environment may allow for multiple graphic designs (and their associated design files) to be loaded and rendered in the design environment, the design environment itself may be considered the root node of the tree data structure. Different visual assets may be represented by different nodes in the tree data structure. For example, a design file associated with a graphic design may be represented as a first-level child node of the tree data structure, and different containers included in the design file may be represented as second-level children nodes in the tree data structure. Generally, a visual asset may be included in the tree data structure as a child node of the immediate parent container in which the visual asset is contained.

Generally, a generative model 202 generates text for a visual asset rendered in the design environment provided by graphic design engine 122 may be triggered by the receipt of a text generation trigger 210 at graphic design engine 122. Text generation trigger 210 may be a defined event within the design environment that indicates that textual content is to be generated for a visual asset rendered in the design environment. These events may include, for example, deleting extant text associated with a visual asset rendered in the design environment, the creation of a visual asset that can contain textual content on a canvas in the design environment, defined keyboard inputs into an active text editing session for a visual asset, selection of all text associated with a visual asset and typing a letter into an active text editing session for a visual asset, or the like.

Graphic design engine 122 generally ingests the text generation trigger 210 and initiates the generation of textual content for a selected visual asset in the graphic design via text suggestion engine 124. In some embodiments, graphic design engine 122 can determine whether text generation trigger 210 is a valid trigger for initiating textual content generation by text suggestion engine 124 based on the context in which text generation trigger 210 is received. For example, if the selected visual asset is a new visual asset in an empty container or otherwise is an asset that lacks other contextual information indicative of the type of content to be included in the visual asset, graphic design engine 122 can determine that text generation trigger 210 is an invalid trigger. In another example, if the visual asset includes textual content generated by text suggestion engine 124 and generative model 202, triggers such as character deletion-based triggers (e.g., ingestion of the backspace or delete key presses on a keyboard) may be deemed an invalid trigger. When graphic design engine 122 determines that text generation trigger 210 is an invalid trigger, no further action may be taken such that textual content generation using text suggestion engine 124 and generative model 202 is not initiated.

In some embodiments, graphic design engine 122 may instruct text suggestion engine 124 to generate suggested textual content for a selected visual asset based on a delay timer started from an initial user interaction with the textual content in the selected visual asset. The delay timer may be used, for example, to determine whether text generation trigger 210 is an actual trigger for generating suggested textual content for the selected visual asset or a mistaken input that can be disregarded. If the text generation trigger 210 is reversed, or if other defined events occur, while the delay timer is active, graphic design engine 122 can determine that text generation trigger 210 is not an actual trigger, and no further action may be taken.

Text suggestion engine 124 generally generates an input prompt for generative model 202 to use in generating textual content for a selected visual asset in the design environment and dispatches the input prompt to generative model 202 for processing.

To generate input prompt 216, text suggestion engine 124 serializes the graphic design associated with the selected visual asset at graphic design serialization block 212 into a textual representation that can be ingested as contextual information by generative model 202. Generally, the textual representation of the graphic design may encode the content and structure of visual assets in the graphic design in a textual format. To serialize the graphic design associated with the selected visual asset, text suggestion engine 124 can identify a top-level container associated with the selected visual asset to identify the specific graphic design (from any number of graphic designs rendered in the design environment) for which a textual representation is to be generated. In some embodiments, to identify the top-level container associated with the visual asset for which textual content is to be generated, text suggestion engine 124 can obtain a tree representation of visual assets rendered in the design environment and traverse the tree to identify the top-level container associated with the selected visual asset. Within the tree representation of visual assets rendered in the design environment, the selected visual asset may be represented by a node in the tree. A inward-outward traversal of the tree representation of visual assets rendered in the design environment can be used to identify the graphic design (and the corresponding design file) containing the selected visual asset. Generally, the inward-outward traversal of the tree may be terminated at the root node representing the design environment. The next-to-last node reached in the inward-outward traversal of the tree representation of visual assets rendered in the design environment may represent the graphic design (and the associated design file) for which text suggestion engine 124 is to generate a textual representation.

Based on the identified design file, text suggestion engine 124 generates a textual representation of the graphic design associated with the selected visual asset. Text suggestion engine generally generates a textual representation of the graphic design based on the textual content each visual asset in the graphic design and other properties of each visual asset. These properties may include, for example, absolute and/or relative position properties, alignment (e.g., with respect to other visual assets in the graphic design, with respect to text contained within a visual asset, etc.), typeface properties, and the like.

In some embodiments, to reduce the computational expense involved in generating predicted textual content for a visual asset, the size of the textual representation of the graphic design may be reduced by identifying a relevant portion of the graphic design associated with the selected visual asset. The relevant portion of the graphic design, or the portion of the graphic design more closely related to the selected visual asset, may be described in more significant detail than less relevant portions of the graphic design. By doing so, a relatively high amount of detail may be included in the textual representation of the graphic design for visual assets that are more closely related to the selected visual asset, and lesser amounts of detail may be included the textual representation of the graphic design for visual assets that are less closely related to the selected visual asset.

In some embodiments, the proximity of a visual asset to the selected visual asset for which textual content is to be generated may be used to determine the amount of detail with which a visual asset is described. Generally, visual assets that are in close proximity to the selected visual asset may be closely related to the selected visual asset and may provide stronger contextual clues as to the textual content to be generated for the selected visual asset. Meanwhile, visual assets that are further away from the selected visual asset may be less closely related to the selected visual asset and may not provide strong contextual clues as to the textual content to be generated for the selected visual asset.

In another example, the container in which the selected visual asset is contained may be used to determine the amount of detail with which a visual asset is described. The container in which the selected visual asset is contained may be identified in the tree representation of the design environment as the visual asset associated with a node that is an immediate or indirect parent node to the selected visual asset. Generally, text suggestion engine 124 can generate a textual representation of the graphic design with a detailed description of visual assets in the container containing the selected visual asset and less detailed descriptions of visual assets in other containers in the graphic design.

In some embodiments, in generating the textual representation of the graphic design, various semantic compression techniques can be used to generate a semantically lossless, but compacted, representation of visual assets in the graphic design. For example, text suggestion engine 124 can generate a textual representation of the graphic design with an uncompressed representation (or serialization) of the selected visual asset and related visual assets (e.g., visual assets in the same container as the selected visual asset, visual assets within a threshold proximity to the selected visual asset, etc.). The uncompressed representation (or serialization) of a visual asset may include the textual content contained within a visual asset, absolute and relative positioning information, an identity of a parent container for the visual asset, and other information that may be relevant to the textual content of the visual asset and surrounding visual assets. Meanwhile, for visual assets that are not sufficiently related, text suggestion engine 124 can generate a textual summary of these assets that retains the semantic meaning of these visual assets but is compressed in size relative to an uncompressed representation (or serialization) of the visual asset.

At input prompt generation block 214, text suggestion engine 124 generates an input prompt 216 based, at least in part, on the textual representation of the graphic design generated at graphic design serialization block 212. To generate the input prompt 216, text suggestion engine creates a prompt instructing the generative model 202 to generate textual content for the suggested visual asset using at least the textual representation of the graphic design as context. In some embodiments, the prompt may include additional information, such as a snapshot of the graphic design containing the selected visual asset, historical and/or current user interaction with the design environment, textual content deleted from the selected visual asset, or other information that may also provide contextual information usable by the generative model 202 in generating suggested textual content for the visual asset. In some embodiments, text suggestion engine 124 can generate the input prompt 216 with additional instructions that may be defined a priori, by user-specific configuration, or the like. These additional instructions may define, for example, a maximum length of the text to be generated by the generative model 202 in response to input prompt 216, a minimum confidence threshold for the generated text, or the like.

After text suggestion engine 124 generates input prompt 216, text suggestion engine 124 outputs input prompt 216 to generative model 202 for processing. While generative model 202 is illustrated as a separate component from text suggestion engine 124, it should be recognized that generative model 202 may be a service remote from text suggestion engine 124 (e.g., deployed on the same device as that on which text suggestion engine 124 is deployed or a device remote from that on which text suggestion engine 124 is deployed) or part of text suggestion engine 124. Generative model 202 generates suggested textual content 218 based on the input prompt 216 and returns the generated suggested textual content 218 to text suggestion engine 124. Text suggestion engine 124 can then pass the suggested textual content 218 to graphic design engine 122, and upon receipt, graphic design engine 122 can render the suggested textual content at textual content rendering block 220.

Generally, in rendering the suggested textual content 218, text suggestion engine 124 can render the suggested textual content 218 in the selected visual asset using graphical properties indicating that the selected visual asset includes the suggested textual content 218. For example, graphic design engine 122 can render the selected textual content using a text color or a text format different from that used for other textual content in the design environment (e.g., using a lighter or darker text color, applying italics, underlining, or other formatting to the suggested textual content 218, etc.).

Graphic design engine 122 can subsequently monitor for text input events in the design environment hosted by graphic design engine 122 to determine whether to continue to display the suggested textual content 218 and/or to determine that a user has accepted the suggested textual content 218. If, for example, graphic design engine 122 detects that a user of the design environment has entered the same text character(s) as the leading text character(s) of the suggested textual content 218, then graphic design engine 122 can determine that the suggested textual content 218 should remain displayed in the design environment. Similarly, if graphic design engine 122 detects that a user of the design environment has accepted the suggested textual content 218, then graphic design engine 122 can transform the suggested textual content 218 to the actual textual content associated with the selected visual asset.

If, however, graphic design engine 122 ingests a text deletion event 222, then graphic design engine 122 can determine that the suggested textual content 218 was rejected. In response, at graphic design re-rendering block 224, graphic design engine 122 can re-render the selected visual asset without the suggested textual content 218. Graphic design engine 122 can then discard the suggested textual content 218 and allow a user to associate arbitrary text with the selected visual asset.

In some embodiments, suggested textual content 218 may be a ranked list including a plurality of texts ranked in order of a confidence score associated with each text. In such a case, graphic design engine 122 can initially render the highest-ranked text in suggested textual content 218 at textual content rendering block 220. If a text deletion event 222 is received in respect of the highest-ranked text in suggested textual content 218, graphic design engine 122 can render the next highest-ranked text in suggested textual content 218 at graphic design re-rendering block 224. By doing so, embodiments of the present disclosure may allow for multiple suggestions to be presented to a user of graphic design engine without executing subsequent inferencing operations using generative model 202 after a text deletion event 222 is received.

In some embodiments, the design environment hosted by graphic design engine 122 may be a collaborative workspace in which multiple users can simultaneously edit a graphic design. In such a case, textual content rendering block 220 may be executed for the user that selected the visual asset and requested generation of suggested textual content 218 for the visual asset. Until the suggested textual content 218 is accepted by the user of graphic design engine 122, suggested textual content 218 may be displayed to the user that requested generation of suggested textual content 218. Suggested textual content 218 may not be displayed to other users participating in the collaborative workspace.

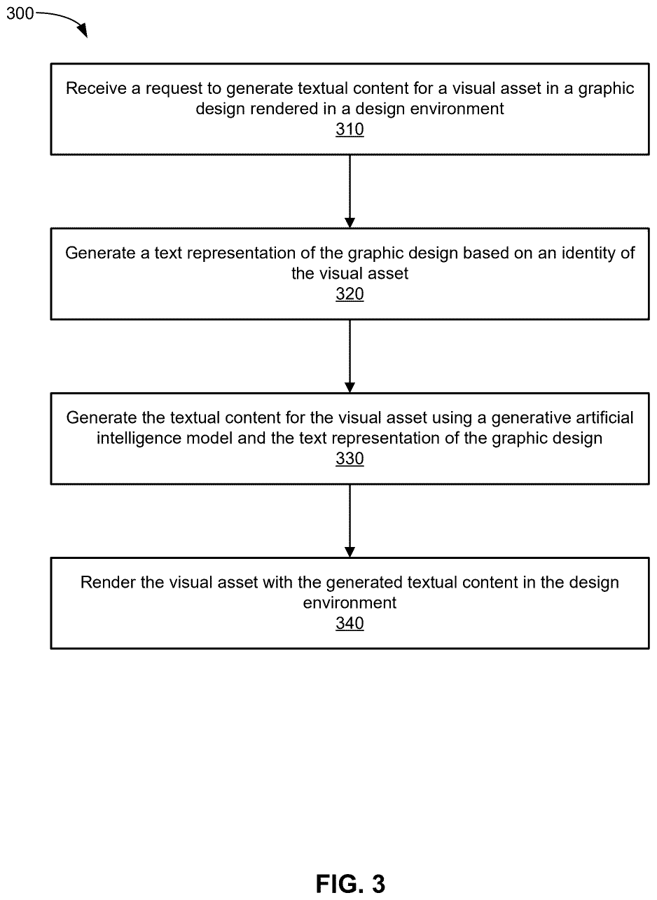

FIG. 3 illustrates example operations 300 for generating textual content for a visual asset rendered in a design environment based on a textual representation of a graphic design associated with the visual asset, according to some embodiments. Operations 300 may be performed, for example, by a computing device on which a graphic design engine and a text suggestion engine that generates suggested textual content for a visual asset based on a textual representation of a graphic design including the visual asset, such as a device including graphic device engine 122 and text suggestion engine 124 illustrated in FIG. 1.

As illustrated, operations 300 begin at block 310, where text suggestion engine 124 receives a request to generate textual content for a visual asset in a graphic design rendered in a design environment.

In some embodiments, the request to generate textual content for the visual asset in the graphic design may include various interactions with the visual asset in the design environment. Generally, these interactions may include an explicit request to generate suggested text for the visual asset (e.g., via selection of a command in a contextual menu associated with the visual asset), deletion of extant text associated with the visual asset, or the like. In some embodiments, user input into the design environment may be monitored with a time delay to determine whether a triggering event has occurred or if an input that would typically constitute a triggering event was not actually a triggering event (e.g., was reversed before expiry of a timer).

At block 320, text suggestion engine 124 generates a text representation of the graphic design based on an identity of the visual asset.

In some embodiments, text suggestion engine 124 generates the text representation of the graphic design based on serializing the graphic design into a textual format. The textual format may generally encode the content and the structure of the graphic design.

In some embodiments, to serialize the graphic design, text suggestion engine 124 identifies a top-level visual asset in the design environment in which the visual asset is contained. Text suggestion engine 124 can then generate a textual representation of the graphic design based on traversing a tree representing visual assets contained within the top-level visual asset. Generally, the top-level visual asset may be represented as a root node of the tree and the visual assets contained within being represented as child nodes of the root node in the tree. The encoded structure of the graphic design may include, for example, positional information associated with visual assets in the graphic design. This positional information may include, for example, absolute and/or relative position information. Absolute position information may include, for example, pixel coordinates at which a visual asset is located on a canvas in the design environment. Relative position information may include, for example, information identifying neighboring visual assets, relative alignment of the visual asset relative to neighboring visual assets and/or the container in which the visual asset is contained, or the like.

In some embodiments, text suggestion engine 124 generates the text representation of the graphic design by identifying a relevant portion of the graphic design based on an identity of the visual asset. The relevant portion of the graphic design may be serialized into a textual format that encodes the content and structure of the relevant portion of the graphic design.

In some embodiments, to identify the relevant portion of the graphic design, text suggestion engine 124 identifies one or more neighboring visual assets in the graphic design to the visual asset. Text suggestion engine 124 generates the set of visual assets to serialize based on the visual asset and the one or more neighboring visual assets. In some embodiments, text suggestion engine 124 can identify the neighboring visual assets by identifying a parent container associated with the visual asset and selecting visual assets included in the parent container as the one or more neighboring visual assets.

In some embodiments, text suggestion engine 124 can generate the text representation of the graphic design by partitioning the graphic design into a first portion associated with the visual asset and one or more contextually relevant visual assets and a second portion associated with visual assets other than the visual asset and the one or more contextually relevant assets. The first portion may include, for example visual assets that are within a threshold distance from the visual asset, visual assets included in the same container as the visual asset, or the like. Text suggestion engine 124 serializes the graphic design at a first level of detail for the first portion and a second level of detail for the second portion. Generally, the second level of detail may include less information than the first level of detail. In some embodiments, text suggestion engine 124 can serialize the graphic design at the first level of detail for the first portion by generating a textual representation of the visual asset and the one or more contextually relevant visual assets including text and positioning data associated with the visual asset and the one or more contextually relevant visual assets. Meanwhile, text suggestion engine 124 can serialize the graphic design at the second level of detail for the second portion by generating a semantically compressed representation of visual assets in the graphic design other than the visual asset and the one or more contextually relevant visual assets.

At block 330, text suggestion engine 124 generates the textual content for the visual asset using a generative artificial intelligence model and the text representation of the graphic design.

At block 340, text suggestion engine 124 renders the visual asset with the generated textual content in the design environment.

In some embodiments, the design environment may be a collaborative workspace in which multiple users can collaborate in editing a graphic design. In such a case, text suggestion engine 124 can render the visual asset with the generated textual content in the design environment for a user from which the request to generate textual content was received. The generated textual content may not be rendered for other users participating in a collaborative workspace in which the design environment is hosted until the user from which the request was received has accepted the generated textual content.

In some embodiments, operations 300 further include text suggestion engine 124 receiving textual input defining text to be displayed in the visual asset. Based on determining that the textual input does not match a beginning set of characters associated with the generated textual content, text suggestion engine 124 can render the visual asset with the received textual input instead of the generated textual content.

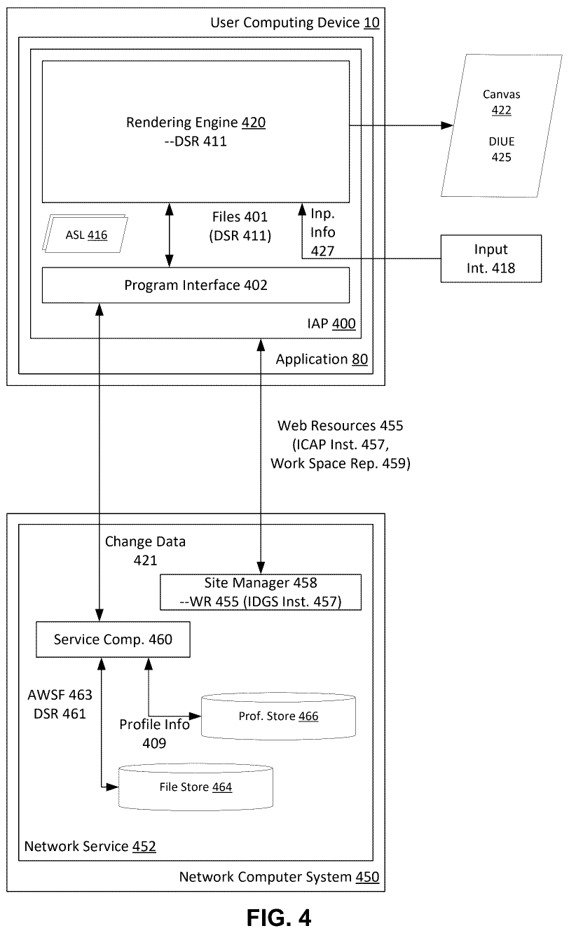

FIG. 4 illustrates a network computing system to implement an interactive application platform on a user computing device, according to some embodiments. A network computing system such as illustrated in FIG. 4 can be implemented using one or more servers which communicate with user computing devices over one or more networks. The network computer system 450 illustrated in FIG. 4 may correspond, for example, to the computing device 100 illustrated in FIG. 1 and can be used to efficiently generate contextually-accurate suggested textual content for visual assets in a design environment.

In some embodiments, the network computing system 450 performs operations to enable an interactive application platform (“IAP 400”) to be implemented on user computing devices 10. In some embodiments, the IAP 400 can be implemented by the user initiating a session (e.g., user accessing a website) to receive programmatic resources of the IAP 400. A browser component executes the programmatic resources to implement the IAP 400, with functionality to receive user input and to render content that is based on or responsive to user input. As described, the IAP 400 is implemented to enable the user to create various types of content, such as interactive graphic designs, art, whiteboard content, program code renderings, presentations, and/or textual content. As further described, the IAP 400 can include logic (“ASL 416”) for implementing one or more application services, where each application service is implemented through the IAP 400 to provide a corresponding set of functionality and user experience. The IAP 400 also implements the application services to share some resources, such as the canvas, workspace file or library of design elements. Further, the IAP 400 enables multiple application services to be used during a given online session and/or with respect to a particular application service.

According to some embodiments, a user of computing device 10 operates web-based application 80 to access a network site, where programmatic resources are retrieved and executed to implement the IAP 400. The web-based application 80 can execute scripts, code and/or other logic (the “programmatic components”) to implement functionality of the IAP 400. In some embodiments, the web-based application 80 can correspond to a commercially available browser, such as GOOGLE CHROME (developed by GOOGLE, INC.) or SAFARI (developed by APPLE, INC.). In some embodiments, the processes of the IAP 400 can be implemented as scripts and/or other embedded code which web-based application 80 downloads from a network site. For example, the web-based application 80 can execute code that is embedded within a webpage to implement processes of the IAP 400. The web-based application 80 can also execute the scripts to retrieve other scripts and programmatic resources (e.g., libraries) from the network site and/or other local or remote locations. By way of example, the web-based application 80 may execute JAVASCRIPT embedded in an HTML resource (e.g., web-page structured in accordance with HTML 5.0 or other versions, as provided under standards published by W3C or WHATWG consortiums). In some embodiments, the rendering engine 420 may utilize graphics processing unit (GPU) accelerated logic, such as provided through WebGL (Web Graphics Library) programs which execute Graphics Library Shader Language (GLSL) programs that execute on GPUs.

The IAP 400 can be implemented as part of a network service, where web-based application 80 communicates with one or more remote computers (e.g., server used for a network service) to execute processes of the IAP 400. The web-based application 80 retrieves some or all of the programmatic resources for implementing the IAP 400 from a network site. The web-based application 80 may also access various types of data sets in providing the IAP 400. The data sets can correspond to files and design libraries (e.g., predesigned design elements), which can be stored remotely (e.g., on a server, in association with an account) or locally. In some embodiments, the network computer system 450 provides a shared design library which the user computing device 10 can use with any of the application services provided through the IAP 400. In this way, the user may initiate a session to implement the IAP 400 for the purpose of creating or editing the workspace file, as rendered on the canvas 422, in accordance with one of multiple collaborative application services of the IAP 400.

In some embodiments, the IAP 400 includes a program interface 402, an input interface 418 and a rendering engine 420. The program interface 402 can include one or more processes which execute to access and retrieve programmatic resources from local and/or remote sources. In an implementation, the program interface 402 can generate, for example, a canvas 422, using programmatic resources which are associated with web-based application 80 (e.g., HTML 5.0 canvas). As an addition or variation, the program interface 402 can trigger or otherwise cause the canvas 422 to be generated using programmatic resources and data sets (e.g., canvas parameters) which are retrieved from local (e.g., memory) or remote sources (e.g., from network service).

The program interface 402 may also retrieve programmatic resources that include an application framework for use with canvas 422. The application framework can include data sets which define or configure, for example, a set of interactive graphic tools that integrate with the canvas 422 and which comprise the input interface 418, to enable the user to provide input to generate or update content rendered on the canvas 422.

According to some embodiments, the input interface 418 can be implemented as a functional layer that is integrated with the canvas 422 to detect and interpret user input. The input interface 418 can, for example, process a user's interaction with an input mechanism (e.g., pointer device, keyboard) of the user computing device, to detect, for example, cursor positioning/movement with respect to the canvas 422, hover input (e.g., pre-selection input), selection input (e.g., clicks or double clicks), shortcuts (e.g., keyboard inputs) and other inputs. In processing a user's interaction with a pointer device, the input interface 418 can use a reference of the canvas 422 to identify a screen location of a user's cursor as the user moves or otherwise interacts with the pointer device. Additionally, the input interface 418 can interpret an input action of the user based on the location of the detected input (e.g., whether the position of the input indicates selection of a tool, an object rendered on the canvas, or region of the canvas), the frequency of the detected input in a given time period (e.g., double-click), and/or the start and end position of an input or series of inputs (e.g., start and end position of a click and drag), as well as various other input types which the user can specify (e.g., right-click, screen-tap, etc.) through one or more input devices. In some embodiments, the input interface 418 can interpret, for example, a series of inputs as a design tool selection (e.g., shape selection based on location of input), as well as inputs to define attributes (e.g., dimensions) of a selected shape. In some embodiments, the input interface 418 can interpret a continuous input (corresponding to a continuous movement of the user's pointer device) as selecting a tool (e.g., shape too) and canvas location where an output of the selected tool is to appear.

In some embodiments, the IAP 400 includes application service logic 416 to enable multiple application services to be utilized during a given user session, where each application service provides the user with a particular functionality and/or user experience. As described by some embodiments, each application service is implemented by the IAP 400 utilizing a corresponding application service logic 416 to configure the interface component 418, rendering engine 420 and/or other components of the IAP 400 to provide the functionality and user experience of the corresponding application service. In this way, the IAP 400 enables the user to operate multiple application services during one online session. Further, the different application services can share resources, including programmatic resources of the IAP 400, such as canvas 422. In this way, each application service can contribute content to and/or utilize features and content provided with the canvas 422 during a given session. Still further, the application services can be implemented as alternative modalities of IAP 400, such that the user can toggle between modes, where each mode provides a particular functionality and user experience. In some embodiments, each application service can utilize a common workspace file associated with the user. By default, a computing device that opens the workspace file can utilize a default application service to access and/or update that workspace file. The user may also switch the mode of operation of the IAP 400 to utilize a different application service to access, use and/or update the workspace file.

The network computing system 450 can include a site manager 458 to manage a website where a set of web-resources 455 (e.g., webpage) are made available for the web-based application 80 of user computing devices 10. The web-resources 455 can include instructions, such as scripts or other logic (“ICAP instructions 457”), which are executable by browsers or web components of user computing devices. The web resources 455 can also include (i) resources that are to be shared as between application services, provided to the user computing devices in connection with the user computing devices utilizing either of the application services, and (ii) application specific resources, which execute on the user computing devices for a particular one of the available application services. The web resources 455 can also include a design library of design elements that is partially or fully shared as between the application services. The library of design elements can enable the user to select predetermined design elements for use on the canvas 422 in connection with the user utilizing either of the application services.

In some variations, once the computing device 10 accesses and downloads the web-resources 455, web-based application 80 executes the IAP instructions 457 to implement functionality as described above. For example, the IAP instructions 457 can be executed by web-based application 80 to initiate the program interface 402 on the user computing device 10. The initiation of the program interface 402 may coincide with the establishment of, for example, a web-socket connection between the program interface 402 and a service component 460 of the network computing system 450.

In some embodiments, the web-resources 455 includes logic which web-based application 80 executes to initiate one or more processes of a program interface 402, causing the IAP 400 to retrieve additional programmatic resources and data sets for implementing functionality as described by examples. The web resources 455 can, for example, embed logic (e.g., JAVASCRIPT code), including GPU accelerated logic, in an HTML page for download by computing devices of users. The program interface 402 can be triggered to retrieve additional programmatic resources and data sets from, for example, the network service 452, and/or from local resources of the computing device 10, in order to implement each of the multiple application services of the IAP 400. For example, some of the components of the IAP 400 can be implemented through webpages that can be downloaded onto the computing device 10 after authentication is performed, and/or once the user performs additional actions (e.g., download one or more pages of the workspace associated with the account identifier). Accordingly, in examples as described, the network computing system 450 can communicate the IAP instructions 457 to the computing device 10 through a combination of network communications, including through downloading activity of web-based application 80, where the IAP instructions 457 are received and executed by web-based application 80.

The computing device 10 can use web-based application 80 to access a website of the network service 452 to download the webpage or web resource. Upon accessing the website, web-based application 80 can automatically (e.g., through saved credentials) or through manual input, communicate an account identifier to the service component 460. In some embodiments, web-based application 80 can also communicate one or more additional identifiers that correlate to a user identifier.

Additionally, in some embodiments, the service component 460 can use the user or account identifier of the user identifier to retrieve profile information 409 from a user profile store 466. As an addition or variation, profile information 409 for the user can be determined and stored locally on the user's computing device 10.

The service component 460 can also retrieve the files of an active workspace (“active workspace files 463”) that are linked to the user account or identifier from a file store 464. The profile store 466 can also identify the workspace that is identified with the account and/or user, and the file store 464 can store the data sets that comprise the workspace. The data sets stored with the file store 464 can include, for example, the pages of a workspace and one or more data structure representations 461 for the design under edit which is renderable from the respective active workspace files.

As an addition or variation, each file can be associated with metadata that identifies the application service that was used to create the particular file. In some embodiments, the metadata identifies the default application service for viewing, utilizing or otherwise updating the application service.

Additionally, in some embodiments, the service component 460 provides a representation 459 of the workspace associated with the user to the web-based application 80, where the representation identifies, for example, individual files associated with the user and/or user account. The workspace representation 459 can also identify a set of files, where each file includes one or multiple pages, and each page including objects that are part of a design interface.

On the user device 10, the user can view the workspace representation through web-based application 80, and the user can elect to open a file of the workspace through web-based application 80. In some embodiments, upon the user electing to open one of the active workspace files 463, web-based application 80 initiates the canvas 422. For example, the IAP 40 can initiate an HTML 5.0 canvas as a component of web-based application 80, and the rendering engine 120 can access one or more data structures representations 411 of content rendered on the canvas 422.

The IAP 400 utilizes application service logic 416 to implement multiple modes of operation, where each mode corresponds to an application service. As described, the application service logic 416 associated with each service application can include instructions and data for configuring the components of IAP 400 to include functionality and features of the corresponding application service. Accordingly, the application service logic 416 can, for example, configure the application framework and/or input interface 418 to differ in form, functionality and/or configuration as between the alternative modes of the IAP 400. Additionally, the type of actions and interactions which the user can perform to register input can vary based on the modes of operation. Still further, the different modes of operation can include different input or user-interface features for the user to select and use for inclusion on the canvas 422. By way of example, when the IAP 400 is operating in a mode for whiteboarding service application, the program interface 402 can provide input features to enable a user to select a design element that is in the form of a “sticky note,” while in an alternative mode for an interactive graphic design service application, the “sticky note feature” is not available. However, in the alternative mode, the user may be able to select anyone of numerous possible shapes or previously designed objects which the user can write textual messages in for display on the canvas 422.

Additionally, the application service logic 416 can configure the operation of the rendering engine 420, such that the functionality and behavior of the rendering engine 420 differs as between different application services. In this way, the rendering engine 420 functions to provide alternative behaviors for different modes of operation, coinciding with the particular service application that is active. By way of example, the configuration of the rendering engine 420 can affect the appearance of the canvas 422, the appearance (e.g., visual attributes) of rendered content elements on the canvas 422, the behavior or representation of user interaction (e.g., whether the user cursor or pointer device is represented on the canvas 422), the type or specific content that is rendered, the physics engine that is used by the rendering engine to represent dynamic events (e.g., the object being moved), what user operations can be performed (e.g., whether select objects can be resized), and the like.

Additionally, each of the application services can utilize a shared library of content elements (e.g., graphic design element), as well as core functionality that enables design elements to be shared and updated between the different application services that are available through the platform. Additionally, the workspace file created and edited through use of one application service can be utilized with the other application service. Moreover, the transition between application services can be seamless—for example, the user computing device 10 can open a workspace file using the first application service (e.g., interactive graphic design application service for UIX design) then seamlessly switch to using the second application service (e.g., whiteboarding application service) with the same file, without closing the workspace file. In some embodiments, each application service enables the user to update the workspace file even while the workspace file is in use by other computing devices (e.g., such as in a collaborative environment). In some embodiments, the user can mode switch the IAP 400 to switch which application service is in use, with each application service utilizing the workspace file.

### EXAMPLE CLAUSES

Various aspects of the present disclosure are described in the following numbered clauses.

1. In some embodiments, a processor-implemented method, comprising: receiving a request to generate textual content for a visual asset in a graphic design rendered in a design environment; generating a text representation of the graphic design based on an identity of the visual asset; generating the textual content for the visual asset using a generative artificial intelligence model and the text representation of the graphic design; and rendering the visual asset with the generated textual content in the design environment.

2. The method of clause 1, wherein generating the text representation of the graphic design comprises serializing the graphic design into a textual format, the textual format encoding content and structure of the graphic design.

3. The method of clause 2, wherein serializing the graphic design comprises: identifying a top-level visual asset in the design environment in which the visual asset is contained; and generating a textual representation of the graphic design based on traversing a tree representing visual assets contained within the top-level visual asset, the top-level visual asset being represented as a root node of the tree and the visual assets contained within being represented as child nodes of the root node in the tree.

4. The method of any of clauses 2 or 3, wherein the encoded structure of the graphic design comprises positional information associated with visual assets in the graphic design.

5. The method of any of clauses 1 through 4, wherein generating the text representation of the graphic design comprises: identifying a relevant portion of the graphic design based on an identity of the visual asset; and serializing the relevant portion of the graphic design into a textual format, the textual format encoding content and structure of the relevant portion of the graphic design.

6. The method of clause 5, wherein identifying the relevant portion of the graphic design comprises: identifying one or more neighboring visual assets in the graphic design to the visual asset; and generating a set of visual assets to serialize based on the visual asset and the one or more neighboring visual assets.

7. The method of clause 6, wherein identifying the one or more neighboring visual assets comprises: identifying a parent container associated with the visual asset; and selecting visual assets included in the parent container as the one or more neighboring visual assets.

8. The method of any of clauses 1 through 7, wherein generating the text representation of the graphic design comprises: partitioning the graphic design into a first portion associated with the visual asset and one or more contextually relevant visual assets and a second portion associated with visual assets other than the visual asset and the one or more contextually relevant assets; and serializing the graphic design at a first level of detail for the first portion and a second level of detail for the second portion, the second level of detail including less information than the first level of detail.

9. The method of clause 8, wherein serializing the graphic design at the first level of detail for the first portion comprises generating a textual representation of the visual asset and the one or more contextually relevant visual assets including text and positioning data associated with the visual asset and the one or more contextually relevant visual assets.

10. The method of any of clauses 8 or 9, wherein serializing the graphic design at the second level of detail for the second portion comprises generating a semantically compressed representation of visual assets in the graphic design other than the visual asset and the one or more contextually relevant visual assets.

11. The method of any of clauses 1 through 10, wherein the request to generate textual content comprises deletion of textual content associated with the visual asset.

12. The method of any of clauses 1 through 11, further comprising: receiving textual input defining text to be displayed in the visual asset; and based on determining that the textual input does not match a beginning set of characters associated with the generated textual content, rendering the visual asset with the received textual input instead of the generated textual content.

13. The method of any of clauses 1 through 12, wherein the rendering the visual asset with the generated textual content in the design environment is performed for a user from which the request to generate textual content was received but not for other users participating in a collaborative workspace in which the design environment is hosted.

14. A processing system, comprising: at least one memory having executable instructions thereon; and one or more processors configured to execute the executable instructions to cause the processing system to perform the method of any of clauses 1 through 13.

15. A processing system, comprising: means for performing the method of any of clauses 1 through 13.

16. A non-transitory computer-readable medium having executable instructions stored thereon which, when processed by one or more processors, causes the one or more processors to perform the method of any of clauses 1 through 13.

Any and all combinations of any of the claim elements recited in any of the claims and/or any elements described in this application, in any fashion, fall within the contemplated scope of the present invention and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A processor-implemented method, comprising:
receiving a request to generate textual content for a visual asset in a graphic design rendered in a design environment;
generating a text representation of the graphic design based on an identity of the visual asset;
generating the textual content for the visual asset using a generative artificial intelligence model and the text representation of the graphic design; and
rendering the visual asset with the generated textual content in the design environment.

2. The method of claim 1, wherein generating the text representation of the graphic design comprises serializing the graphic design into a textual format, the textual format encoding content and structure of the graphic design.

3. The method of claim 2, wherein serializing the graphic design comprises:
identifying a top-level visual asset in the design environment in which the visual asset is contained; and
generating a textual representation of the graphic design based on traversing a tree representing visual assets contained within the top-level visual asset, the top-level visual asset being represented as a root node of the tree and the visual assets contained within being represented as child nodes of the root node in the tree.

4. The method of claim 2, wherein the encoded structure of the graphic design comprises positional information associated with visual assets in the graphic design.

5. The method of claim 1, wherein generating the text representation of the graphic design comprises:
identifying a relevant portion of the graphic design based on an identity of the visual asset; and
serializing the relevant portion of the graphic design into a textual format, the textual format encoding content and structure of the relevant portion of the graphic design.

6. The method of claim 5, wherein identifying the relevant portion of the graphic design comprises:
identifying one or more neighboring visual assets in the graphic design to the visual asset; and
generating a set of visual assets to serialize based on the visual asset and the one or more neighboring visual assets.

7. The method of claim 6, wherein identifying the one or more neighboring visual assets comprises:
identifying a parent container associated with the visual asset; and
selecting visual assets included in the parent container as the one or more neighboring visual assets.

8. The method of claim 1, wherein generating the text representation of the graphic design comprises:
partitioning the graphic design into a first portion associated with the visual asset and one or more contextually relevant visual assets and a second portion associated with visual assets other than the visual asset and the one or more contextually relevant assets; and
serializing the graphic design at a first level of detail for the first portion and a second level of detail for the second portion, the second level of detail including less information than the first level of detail.

9. The method of claim 8, wherein serializing the graphic design at the first level of detail for the first portion comprises generating a textual representation of the visual asset and the one or more contextually relevant visual assets including text and positioning data associated with the visual asset and the one or more contextually relevant visual assets.

10. The method of claim 8, wherein serializing the graphic design at the second level of detail for the second portion comprises generating a semantically compressed representation of visual assets in the graphic design other than the visual asset and the one or more contextually relevant visual assets.

11. The method of claim 1, wherein the request to generate textual content comprises deletion of textual content associated with the visual asset.

12. The method of claim 1, further comprising:
receiving textual input defining text to be displayed in the visual asset; and
based on determining that the textual input does not match a beginning set of characters associated with the generated textual content, rendering the visual asset with the received textual input instead of the generated textual content.

13. The method of claim 1, wherein the rendering the visual asset with the generated textual content in the design environment is performed for a user from which the request to generate textual content was received but not for other users participating in a collaborative workspace in which the design environment is hosted.

14. A processing system, comprising:
at least one memory having executable instructions stored thereon; and
one or more processors configured to execute the executable instructions to cause the processing system to:
receive a request to generate textual content for a visual asset in a graphic design rendered in a design environment;
generate a text representation of the graphic design based on an identity of the visual asset;
generate the textual content for the visual asset using a generative artificial intelligence model and the text representation of the graphic design; and
render the visual asset with the generated textual content in the design environment.

15. The processing system of claim 14, wherein to generate the text representation of the graphic design, the one or more processors are configured to cause the processing system to serialize the graphic design into a textual format, the textual format encoding content and structure of the graphic design.

16. The processing system of claim 14, wherein to generate the text representation of the graphic design, the one or more processors are configured to cause the processing system to:
identify a relevant portion of the graphic design based on an identity of the visual asset; and
serialize the relevant portion of the graphic design into a textual format, the textual format encoding content and structure of the relevant portion of the graphic design.

17. The processing system of claim 16, wherein to identify the relevant portion of the graphic design, the one or more processors are configured to cause the processing system to:
identify one or more neighboring visual assets in the graphic design to the visual asset; and
generate a set of visual assets to serialize based on the visual asset and the one or more neighboring visual assets.

18. The processing system of claim 17, wherein to identify the one or more neighboring visual assets, the one or more processors are configured to cause the processing system to:
identify a parent container associated with the visual asset; and
select visual assets included in the parent container as the one or more neighboring visual assets.

19. The processing system of claim 14, wherein to generate the text representation of the graphic design, the one or more processors are configured to cause the processing system to:
partition the graphic design into a first portion associated with the visual asset and one or more contextually relevant visual assets and a second portion associated with visual assets other than the visual asset and the one or more contextually relevant assets; and
serialize the graphic design at a first level of detail for the first portion and a second level of detail for the second portion, the second level of detail including less information than the first level of detail.

20. A non-transitory computer-readable medium having executable instructions stored thereon which, when executed by one or more processors, performs an operation comprising:
receiving a request to generate textual content for a visual asset in a graphic design rendered in a design environment;
generating a text representation of the graphic design based on an identity of the visual asset;
generating the textual content for the visual asset using a generative artificial intelligence model and the text representation of the graphic design; and
rendering the visual asset with the generated textual content in the design environment.
